(19) United States
(12) Patent Application Publication
(10) Pub. No.: US 2026/0363009 A1
(43) Pub. Date: Nov. 12, 2026

(54) SUBSTRATE PROCESSING METHOD

(71) Applicant: SCREEN Holdings Co., Ltd., Kyoto (JP)

(72) Inventor: Taiki HINODE, Santa Clara, CA (US)

(21) Appl. No.: 19/331,997

(22) Filed: Sep. 17, 2025

Related U.S. Application Data
(60) Provisional application No. 63/801,108, filed on May 6, 2025.

(51) Int. Cl. H10P 70/00; B08B 3/04; B08B 3/08; F26B 5/08

(52) U.S. Cl. CPC H10P 70/20; B08B 3/041; B08B 3/08; F26B 5/08

(57) ABSTRACT

A substrate processing method includes supplying phosphoric acid having a temperature higher than room temperature onto an upper surface of a substrate while rotating the substrate in a horizontal posture, supplying first hot water which is pure water having a temperature higher than room temperature onto the upper surface of the substrate while rotating the substrate in a horizontal posture, supplying an alkaline chemical liquid onto the upper surface of the substrate while rotating the substrate in a horizontal posture, and supplying second hot water which is pure water having a temperature higher than room temperature onto the upper surface of the substrate while rotating the substrate in a horizontal posture.

### CROSS REFERENCE TO RELATED APPLICATIONS

This application claims the benefit of U.S. Provisional Application No. 63/801,108 filed on May 6, 2025, and the contents of which are hereby incorporated by reference.

### BACKGROUND OF THE INVENTION

### 1. Field of the Invention

The present invention relates to a substrate processing method that processes substrates. The substrates include a semiconductor wafer, a substrate for a FPD (flat panel display) such as a liquid crystal display and an organic EL (electroluminescence) display, a substrate for an optical disc, a substrate for a magnetic disk, a substrate for a magneto-optical disc, a substrate for a photomask, a ceramic substrate, a substrate for a solar cell, and the like.

### 2. Description of Related Art

JP 2016-42503 A discloses that a phosphoric acid aqueous solution, hot water, SC1, and pure water are sequentially supplied onto a substrate in this order.

### SUMMARY OF THE INVENTION

At least one preferred embodiment of the present invention provides a substrate processing method capable of enhancing cleanliness of a substrate.

A preferred embodiment of the present invention provides a substrate processing method including supplying phosphoric acid having a temperature higher than room temperature onto an upper surface of a substrate while rotating the substrate in a horizontal posture, supplying first hot water, which is pure water having a temperature higher than room temperature, onto the upper surface of the substrate while rotating the substrate in a horizontal posture with the phosphoric acid on the upper surface of the substrate, supplying an alkaline chemical liquid onto the upper surface of the substrate while rotating the substrate in a horizontal posture with the first hot water on the upper surface of the substrate, and supplying second hot water, which is pure water having a temperature higher than room temperature, onto the upper surface of the substrate while rotating the substrate in a horizontal posture with the alkaline chemical liquid on the upper surface of the substrate.

In the preferred embodiment, at least one of the following features may be added to the substrate processing method.

A supply time of the first hot water with respect to the upper surface of the substrate is longer than a supply time of the phosphoric acid with respect to the upper surface of the substrate.

Supplying the phosphoric acid includes supplying the phosphoric acid onto the upper surface of the substrate while rotating the substrate in a horizontal posture at a phosphoric acid supply speed, and supplying the first hot water includes maintaining a state in which an entire area of the upper surface of the substrate is covered with a liquid film of the first hot water while rotating the substrate in a horizontal posture at a first hot water supply speed lower than the phosphoric acid supply speed or stopping the substrate in a horizontal posture.

The substrate processing method further includes supplying a pre-wet liquid onto the upper surface of the substrate while rotating the substrate in a horizontal posture at a pre-wet liquid supply speed before supplying the phosphoric acid onto the upper surface of the substrate, wherein supplying the phosphoric acid includes supplying the phosphoric acid onto the upper surface of the substrate while rotating the substrate in a horizontal posture at the phosphoric acid supply speed lower than the pre-wet liquid supply speed.

A supply time of the alkaline chemical liquid with respect to the upper surface of the substrate is longer than a supply time of the phosphoric acid with respect to the upper surface of the substrate.

Supplying the phosphoric acid includes supplying the phosphoric acid onto the upper surface of the substrate while rotating the substrate in a horizontal posture at a phosphoric acid supply speed, and supplying the alkaline chemical liquid includes supplying the alkaline chemical liquid onto the upper surface of the substrate while rotating the substrate in a horizontal posture at an alkaline chemical liquid supply speed that is equal to or lower than the phosphoric acid supply speed.

Supplying the alkaline chemical liquid includes supplying the alkaline chemical liquid onto the upper surface of the substrate while rotating the substrate in a horizontal posture at an alkaline chemical liquid supply speed to cause the alkaline chemical liquid scattered from the substrate to collide with an inner surface of a cylindrical guard surrounding the substrate around a vertical straight line, and supplying the second hot water includes supplying the second hot water onto the upper surface of the substrate while rotating the substrate in a horizontal posture at a low rotation speed equal to or lower than the alkaline chemical liquid supply speed to cause the second hot water scattered from the substrate to collide with the inner surface of the guard, increasing a rotation speed of the substrate from the low rotation speed to a high rotation speed exceeding the alkaline chemical liquid supply speed while supplying the second hot water onto the upper surface of the substrate, and, supplying the second hot water onto the upper surface of the substrate while rotating the substrate in a horizontal posture at the high rotation speed to cause the second hot water scattered from the substrate to collide with the inner surface of the guard.

The substrate processing method further includes drying the substrate by rotating the substrate at a drying speed higher than the high rotation speed in a state in which the substrate is positioned inside the guard when viewed vertically after supplying the second hot water onto the upper surface of the substrate.

Supplying the phosphoric acid, supplying the first hot water, supplying the alkaline chemical liquid, and supplying the second hot water include supplying the phosphoric acid, the first hot water, the alkaline chemical liquid, and the second hot water onto the upper surface of the substrate while rotating the substrate in a horizontal posture together with a plurality of chuck pins pressed against an end surface of the substrate.

### BRIEF DESCRIPTION OF THE DRAWINGS

FIG. 1A is a schematic plan view showing a layout of a substrate processing apparatus according to a preferred embodiment.

FIG. 1B is a schematic side view of the substrate processing apparatus.

FIG. 2 is a schematic view of an interior of a processing unit when viewed horizontally.

FIGS. 3A and 3B are schematic views showing examples of cross-sections of a substrate before and after being processed by the substrate processing apparatus.

FIG. 4 is a process chart for describing an example of processing of the substrate performed by the substrate processing apparatus.

FIG. 5 is a schematic view of the substrate and the guard viewed horizontally while the substrate is rotated and the processing liquid is discharged toward the upper surface of the substrate.

FIG. 6 is a schematic view of the substrate and the guard viewed horizontally while the substrate is rotated and the processing liquid is discharged toward the upper surface of the substrate.

FIG. 7 is a schematic view of the substrate and the guard viewed horizontally while the substrate is rotated and the processing liquid is discharged toward the upper surface of the substrate.

FIG. 8 is a time chart showing the discharge of the processing liquid, the temperature of the processing liquid, and the rotation speed of the substrate when the processing shown in FIG. 4 is performed.

### DETAILED DESCRIPTION OF PREFERRED EMBODIMENTS

Preferred embodiments of the present invention will be explained in detail with reference to the accompanying drawings.

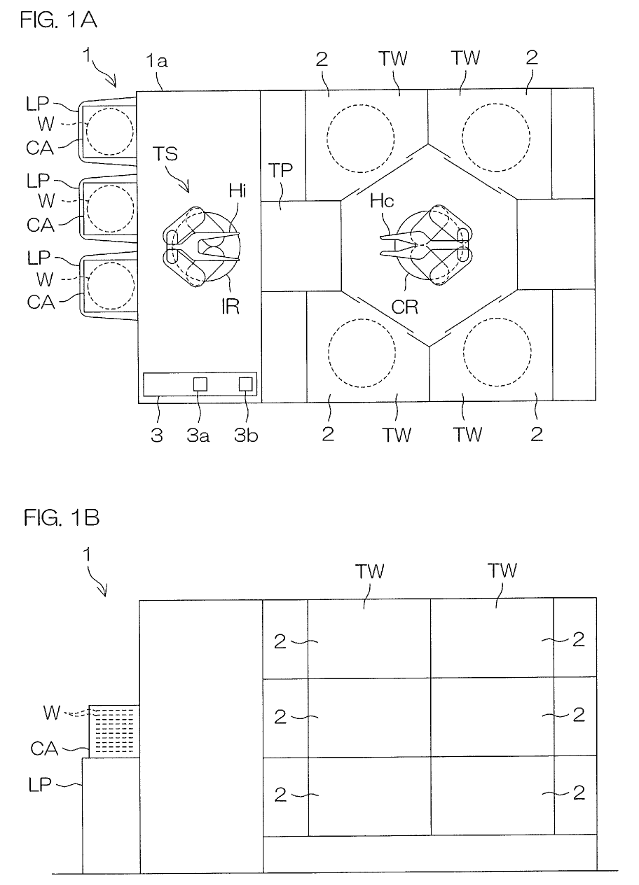

FIG. 1A is a schematic plan view showing a layout of a substrate processing apparatus 1 according to a preferred embodiment. FIG. 1B is a schematic side view of the substrate processing apparatus 1.

As shown in FIG. 1A, the substrate processing apparatus 1 is a single substrate processing type apparatus that processes disk-shaped substrates W such as semiconductor wafers one by one. The substrate processing apparatus 1 includes a load port LP that holds a carrier CA housing a plurality of substrates W, such as a FOUP (Front-Opening Unified Pod), a plurality of processing units 2 that process the substrates W transferred from the carrier CA on the load port LP with a processing fluid such as a processing liquid or processing gas, a transfer system TS that transfers the substrates W between the carrier CA on the load port LP and the plurality of processing units 2, an outer wall 1a that forms an internal space housing the plurality of processing units 2 and the transfer system TS, and a controller 3 that controls the substrate processing apparatus 1.

The plurality of processing units 2 form a plurality of towers TW. FIG. 1A shows an example where four towers TW are formed. As shown in FIG. 1B, a plurality of processing units 2 included in a single tower TW are stacked vertically. As shown in FIG. 1A, the plurality of towers TW form two rows extending in the depth direction (the left-right direction of the paper in FIG. 1A) of the substrate processing apparatus 1 in a plan view. The two rows face each other across a transfer path TP in a plan view.

The transfer system TS includes an indexer robot IR that carries the substrates W into and out from the carrier CA on the load port LP and a center robot CR that carries the substrates W into and out from the processing units 2. The center robot CR is disposed in the transfer path TP. The indexer robot IR is disposed between the load port LP and the center robot CR in a plan view. The indexer robot IR transfers the substrate W to the center robot CR and receives the substrate W from the center robot CR. The same applies to the center robot CR.

The indexer robot IR includes one or more hands Hi that support the substrates W horizontally. The hand Hi is movable in parallel in both the horizontal direction and the vertical direction. The hand Hi is rotatable around a vertical line. The hand Hi can carry in and carry out the substrate W to and from the carrier CA on any of the load ports LP, and can receive and transfer the substrate W from and to the center robot CR.

The center robot CR includes one or more hands Hc that support the substrates W horizontally. The hand Hc is movable in parallel in both the horizontal direction and the vertical direction. The hand Hc is rotatable around a vertical line. The hand Hc can receive and transfer the substrate W from and to the indexer robot IR, and carry in and carry out the substrate W to and from any of the processing units 2.

The controller 3 controls electrical devices and electronic devices provided in the substrate processing apparatus 1. The controller 3 includes at least one computer. The computer includes a CPU (Central Processing Unit) 3a that performs processing of information such as execution of a program and a memory 3b that stores information such as a program to be executed by the CPU 3a. A CPU is also called a processor. The controller 3 controls the substrate processing apparatus 1 to carry out transfer and processing of the substrate W described below. In other words, the controller 3 is programmed to carry out transfer and processing of the substrate W described below.

Next, the processing unit 2 will be described.

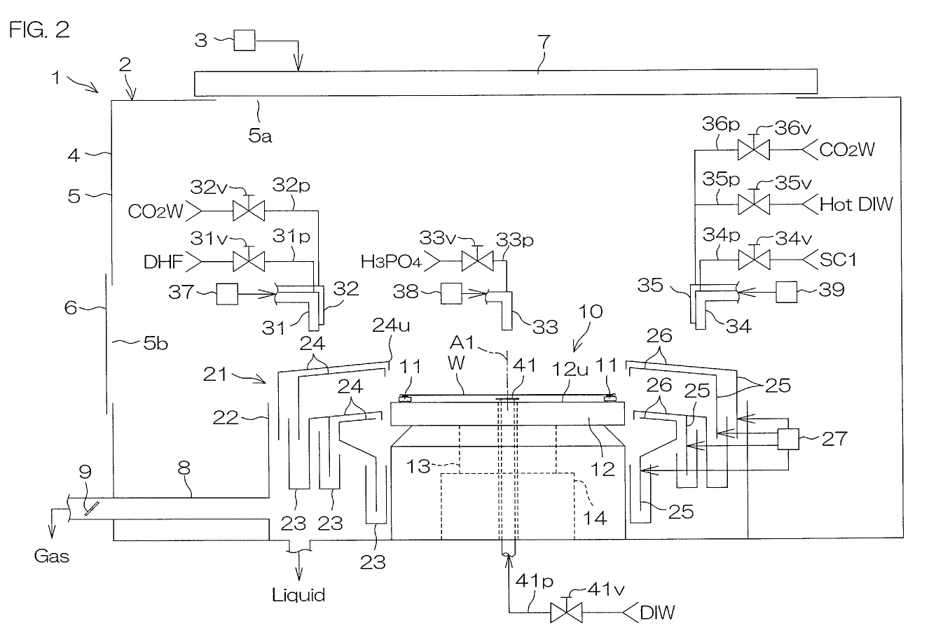

FIG. 2 is a schematic view of an interior of the processing unit 2 when viewed horizontally. DIW in FIG. 2 represents pure water at room temperature (for example, 20 to 30°C), and HotDIW in FIG. 2 represents pure water having a temperature higher than room temperature. Hereinafter, unless otherwise specified, pure water at room temperature is referred to as pure water, and pure water having a temperature higher than room temperature is referred to as hot water. Both the first hot water and the second hot water are hot water.

As shown in FIG. 2, the processing unit 2 includes a chamber 4 that houses the substrate W, a spin chuck 10 that rotates one substrate W around a vertical rotational axis A1 passing through the central portion of the substrate W while holding the substrate W horizontally in the chamber 4.

The chamber 4 includes a box-shaped partition 5 provided with a passing port 5b through which the substrate W passes, and a door 6 that opens and closes the passing port 5b. An FFU 7 (Fan Filter Unit 7) is disposed over an air outlet 5a provided on the upper portion of the partition 5. The FFU 7 constantly supplies clean air (air that has been filtered by a filter) from the air outlet 5a to the chamber 4. The gas in the chamber 4 is discharged from the chamber 4 through a discharged gas duct 8 connected to the bottom portion of a processing cup 21. Thereby, a downflow of clean air is constantly formed inside the chamber 4. The flow rate of discharged gas to be discharged into the discharged gas duct 8 is changed according to the opening degree of an discharged gas valve 9 disposed in the discharged gas duct 8.

The spin chuck 10 includes a disk-shaped spin base 12 horizontally held, a plurality of chuck pins 11 that hold the substrate W horizontally above the spin base 12, a spin shaft 13 that extends downward from the central portion of the spin base 12 along the rotational axis A1, and a spin motor 14 that rotates the spin base 12 and the plurality of chuck pins 11 around the rotational axis A1 by rotating the spin shaft 13. Although the spin chuck 10 includes three or more chuck pins 11, FIG. 2 depicts the number of the chuck pins 11 is two.

The spin chuck 10 is not limited to a mechanical chuck that brings the plurality of chuck pins 11 into contact with the end surface of the substrate W, and may be a vacuum chuck that holds the substrate W horizontally by adsorbing the rear surface (lower surface) of the substrate W, which is a non-device forming surface, onto the upper surface 12u of the spin base 12. When the spin chuck 10 is the mechanical chuck, the plurality of chuck pins 11 correspond to a substrate holder. When the spin chuck 10 is the vacuum chuck, the spin base 12 corresponds to the substrate holder.

The processing unit 2 includes the tubular processing cup 21 that receives the processing liquid scattered from the substrate W. The processing cup 21 includes a plurality of guards 24 that receive the processing liquid discharged outward from the substrate W held by the spin chuck 10, a plurality of cup 23 that receive the processing liquid guided downward by the plurality of guards 24, and a tubular outer wall 22 surrounding the plurality of guards 24 and the plurality of cups 23. FIG. 2 shows an example where four guards 24 and three cups 23 are provided and the outermost cup 23 is integral to the third guard 24 from the top.

The guard 24 includes a cylindrical portion 25 surrounding the spin chuck 10 and an annular ceiling portion 26 extending upward obliquely from the upper end portion of the cylindrical portion 25 toward the rotational axis A1. The plurality of ceiling portions 26 overlap each other vertically, and the plurality of cylindrical portions 25 are concentrically disposed. The annular upper end of the ceiling portion 26 corresponds to the upper end 24u of the guard 24 surrounding the substrate W and the spin base 12 in a plan view. The plurality of cup 23 are disposed under the plurality of cylindrical portions 25, respectively. The cup 23 forms an annular groove that receives the processing liquid guided downward by the guard 24.

The processing unit 2 includes a guard raising/lowering actuator 27 that individually raises and lowers the plurality of guards 24. The guard raising/lowering actuator 27 holds the guard 24 stationary at any position within a range from an upper position to a lower position. FIG. 2 shows a state in which two guards 24 are disposed at the upper position and the remaining two guards 24 are disposed at the lower position. The upper position is a position where the upper end 24u of the guard 24 is disposed above a holding position where the substrate W held by the spin chuck 10 is positioned. The lower position is a position where the upper end 24u of the guard 24 is disposed below the holding position.

The actuator is a device that converts driving energy, which represents electrical, fluid, magnetic, thermal or chemical energy, to mechanical work, that is, motion of a tangible object. The actuator includes an electric motor (rotary motor), linear motor, air cylinder and other devices. If the motion of the actuator is different from the motion of the object, a motion converter may be provided to convert the motion of the actuator into linear motion or rotation. If the actuator is an electric motor and the object is to be moved in a linear motion, a motion converter, such as a ball screw and ball nut, may convert the rotation of the electric motor into linear motion.

The processing unit 2 includes a plurality of nozzles that discharge the processing liquid toward the substrate W held by the spin chuck 10. The plurality of nozzles include a chemical liquid nozzle 31, a chemical liquid nozzle 33, a chemical liquid nozzle 34, a rinse liquid nozzle 32, and a rinse liquid nozzle 35. These five nozzles are nozzles that discharge the processing liquid toward the upper surface of the substrate W held by the spin chuck 10.

FIG. 2 shows an example in which the chemical liquid nozzle 31 discharges DHF (dilute hydrofluoric acid), the chemical liquid nozzle 33 discharges phosphoric acid (aqueous solution of H₃PO₄), and the chemical liquid nozzle 34 discharges SC1 (mixture of ammonia water, hydrogen peroxide solution, and water). The chemical liquid nozzle 31, the chemical liquid nozzle 33, and the chemical liquid nozzle 34 discharge chemical liquids having different temperatures and/or substances. The chemical liquid may be a liquid that contains at least one of sulfuric acid, nitric acid, hydrochloric acid, hydrofluoric acid, phosphoric acid, acetic acid, ammonia water, a hydrogen peroxide solution, organic acid (e.g., such as citric acid or oxalic acid), organic alkaline (e.g., TMAH: tetramethyl ammonium hydroxide), a surface-active agent, and a corrosion inhibitor, or may be a liquid other than those.

The chemical liquid nozzle 31 is connected to chemical liquid piping 31p that guides the chemical liquid. When a chemical liquid valve 31v attached to the chemical liquid piping 31p is opened, the chemical liquid is continuously discharged downward from the discharge port of the chemical liquid nozzle 31. Similarly, the chemical liquid nozzle 33 is connected to chemical liquid piping 33p that guides the chemical liquid. When a chemical liquid valve 33v attached to the chemical liquid piping 33p is opened, the chemical liquid is continuously discharged downward from the discharge port of the chemical liquid nozzle 33. The chemical liquid nozzle 34 is connected to chemical liquid piping 34p that guides the chemical liquid. When a chemical liquid valve 34v attached to the chemical liquid piping 34p is opened, the chemical liquid is continuously discharged downward from the discharge port of the chemical liquid nozzle 34.

Although not shown, the chemical liquid valve 31v includes a valve body provided with an annular valve seat through which the chemical liquid passes, a valve element that can move with respect to the valve seat, and an actuator that moves the valve element between a closed position where the valve element contacts the valve seat and an open position where the valve element is away from the valve seat. The same applies to other valves. The actuator may be a pneumatic actuator or an electric actuator, or may be an actuator other than these. The controller 3 opens and closes the chemical liquid valve 31v and the like by controlling the actuator.

FIG. 2 shows an example in which the rinse liquid nozzle 32 discharges carbonated water, and the rinse liquid nozzle 35 discharges carbonated water or hot water. In FIG. 2, CO₂W represents carbonated water. The carbonated water is pure water in which a carbon dioxide gas is dissolved. The carbonated water and the hot water are both rinse liquids. The rinse liquid may be any of pure water (DIW (Deionized Water)), carbonated water, electrolyzed ionized water, hydrogen water, ozone water, hydrochloric acid water having a dilution concentration (for example, about 1 to 100 ppm) and ammonia water having a dilution concentration (for example, about 1 to 100 ppm), or may be a liquid other than these. The rinse liquid may be organic solvent such as IPA (isopropyl alcohol).

The rinse liquid nozzle 32 is connected to carbonated water piping 32p that guides carbonated water. When a carbonated water valve 32v attached to the carbonated water piping 32p is opened, the carbonated water is continuously discharged downward from the discharge port of the rinse liquid nozzle 32. The rinse liquid nozzle 35 is connected to carbonated water piping 36p that guides carbonated water and hot water piping 35p that guides hot water. When a carbonated water valve 36v attached to the carbonated water piping 36p is opened, the carbonated water is continuously discharged downward from the discharge port of the rinse liquid nozzle 35. When a hot water valve 35v attached to the hot water piping 35p is opened, the hot water is continuously discharged downward from the discharge port of the rinse liquid nozzle 35.

The chemical liquid nozzle 31 may be a scan nozzle that can move horizontally while discharging the chemical liquid toward the substrate W, or may be a fixed nozzle that cannot move horizontally while discharging the chemical liquid toward the substrate W. The same applies to other nozzles. FIG. 2 shows an example in which the chemical liquid nozzle 31, the chemical liquid nozzle 33, the chemical liquid nozzle 34, the rinse liquid nozzle 32, and the rinse liquid nozzle 35 are scan nozzles.

The processing unit 2 includes at least one nozzle actuator that horizontally moves the at least one scan nozzle. FIG. 2 shows an example in which three nozzle actuators are provided. The nozzle actuator 37 is connected to the chemical liquid nozzle 31 and the rinse liquid nozzle 32. The nozzle actuator 38 is connected to the chemical liquid nozzle 33. The nozzle actuator 39 is connected to the chemical liquid nozzle 34 and the rinse liquid nozzle 35. The nozzle actuator 37 horizontally moves the chemical liquid nozzle 31 and the rinse liquid nozzle 32 while maintaining the relative positions of the chemical liquid nozzle 31 and the rinse liquid nozzle 32 constant. The same applies to the nozzle actuator 39.

The nozzle actuator 37 horizontally moves the chemical liquid nozzle 31 and the rinse liquid nozzle 32 between a processing position where the processing liquid discharged from either the chemical liquid nozzle 31 or the rinse liquid nozzle 32 is supplied onto the upper surface of the substrate W and a standby position where the chemical liquid nozzle 31 and the rinse liquid nozzle 32 are positioned around the processing cup 21 in a plan view. The same applies to the nozzle actuator 38 and the nozzle actuator 39. The nozzle actuator 37 may rotate the chemical liquid nozzle 31 and the rinse liquid nozzle 32 around a vertical straight line located outside the processing cup 21, or may horizontally move the chemical liquid nozzle 31 and the rinse liquid nozzle 32 in parallel. The same applies to the nozzle actuator 38 and the nozzle actuator 39.

The plurality of nozzles further include a lower surface nozzle 41 that discharges the processing liquid toward the lower surface of the substrate W held by the spin chuck 10. The lower surface nozzle 41 protrudes upward from a central portion of the upper surface 12u of the spin base 12. Even if the substrate W and the spin chuck 10 rotate, the lower surface nozzle 41 does not rotate. The lower surface nozzle 41 is a fixed nozzle that does not move in any direction.

The lower surface nozzle 41 includes a discharge port that discharges the processing liquid toward the central portion of the lower surface of the substrate W held by the spin chuck 10, and an internal flow path that guides the processing liquid to the discharge port. The discharge port of the lower surface nozzle 41 is disposed above the upper surface 12u of the spin base 12. When the substrate W is held by the spin chuck 10, the discharge port of the lower surface nozzle 41 vertically faces the lower surface of the substrate W. The internal flow path of the lower surface nozzle 41 extends downward from the discharge port of the lower surface nozzle 41 along the rotational axis A1 corresponding to the rotational center of the spin chuck 10.

The lower surface nozzle 41 is connected to rinse liquid piping 41p that guides the rinse liquid. A rinse liquid valve 41v is attached to the rinse liquid piping 41p. When the rinse liquid valve 41v is opened, the rinse liquid such as pure water is continuously discharged upward from the discharge port of the lower surface nozzle 41. The processing liquid discharged from the lower surface nozzle 41 may be the rinse liquid other than pure water, or may be a liquid other than the rinse liquid such as the chemical liquid.

Next, the structure of the substrate W processed by the substrate processing apparatus 1 will be described.

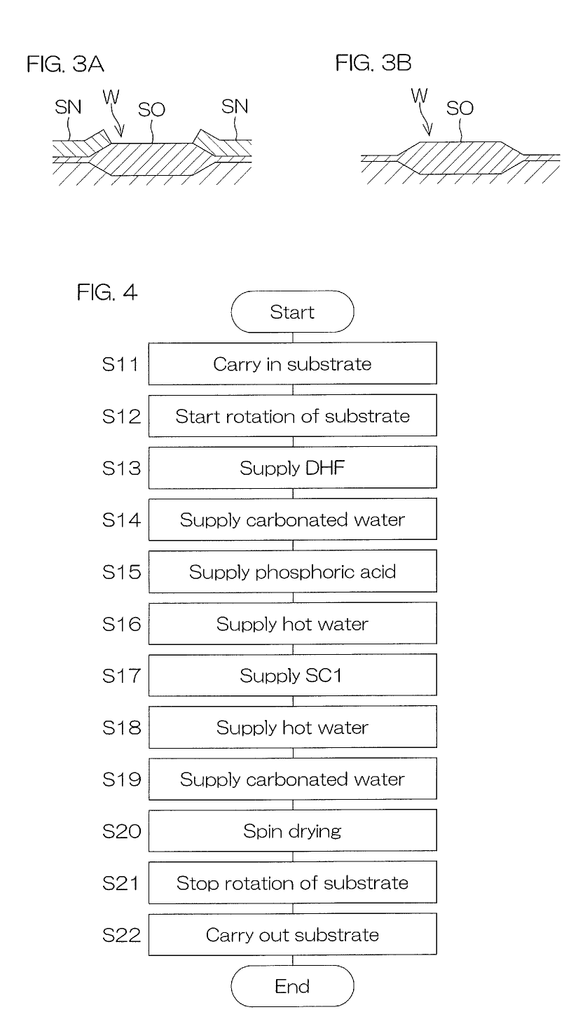

FIGS. 3A and 3B are schematic views showing examples of cross-sections of the substrate W before and after being processed by the substrate processing apparatus 1. FIG. 3A shows the cross-sections of the substrate W before being processed by the substrate processing apparatus 1. FIG. 3B shows the cross-sections of the substrate W after being processed by the substrate processing apparatus 1. As shown in FIG. 3A, the substrate W before being processed by the substrate processing apparatus 1 includes a silicon oxide film SO and a silicon nitride film SN exposed on the upper surface of the substrate W.

In an example of processing of the substrate W to be described below, DHF, carbonated water, phosphoric acid, first hot water, SC1, second hot water, and carbonated water are supplied onto the upper surface of the substrate W shown in FIG. 3A in this order. DHF, phosphoric acid, and SC1 are all chemical liquids. DHF and phosphoric acid are also etching liquids. DHF is an example of an oxide etching liquid to etch silicon oxide. Phosphoric acid is an example of a nitride etching liquid to etch silicon nitride. SC1 is an example of a cleaning chemical liquid to wash away phosphoric acid remaining on the upper surface of the substrate W.

When DHF is supplied onto the substrate W, the surface layer of the silicon oxide film SO is etched, and the silicon oxide film SO other than the surface layer remains on the substrate W. In a case where the surface layer of the silicon nitride film SN is changed to silicon oxide, when DHF is supplied onto the substrate W, the surface layer of the silicon nitride film SN is etched, and the silicon nitride film SN other than the surface layer remains on the substrate W. The chemical liquid supply step (step S13 in FIG. 4) described below is an example of an oxide removing step of removing an oxide from at least one of the silicon oxide film SO and the silicon nitride film SN.

When phosphoric acid is supplied onto the substrate W, the silicon oxide film SO is hardly etched, and the silicon nitride film SN is etched. That is, phosphoric acid etches the silicon nitride film SN at a speed higher than a speed at which the silicon oxide film SO is etched by phosphoric acid. When the phosphoric acid is continuously supplied onto the substrate W, as shown in FIG. 3B, all the silicon nitride films SN are removed from the substrate W, and the silicon oxide film SO remains on the substrate W. Thereby, the silicon nitride film SN is selectively etched with phosphoric acid. The phosphoric acid supply step (step S15 in FIG. 4) to be described below is an example of a selective etching step of removing the silicon nitride film SN from the substrate W while leaving the silicon oxide film SO on the substrate W.

Next, an example of processing of the substrate W will be described.

FIG. 4 is a process chart for describing an example of processing of the substrate W performed by the substrate processing apparatus 1. In the following, FIGS. 1A,2,4, will be referenced.

When the substrate W is to be processed by the substrate processing apparatus 1, a carry-in step of carrying the substrate W into the chamber 4 is performed (step S11 of FIG. 4).

Specifically, in a state in which all of the guards 24 are positioned at the lower positions and all of the scan nozzles are positioned at the standby positions, the center robot CR moves the substrate W on the hand Hc onto the plurality of chuck pins 11 while horizontally supporting the substrate W with the hand Hc. Thereafter, the center robot CR moves the hand Hc out of the chamber 4. After the substrate W is placed on the plurality of chuck pins 11, all the chuck pins 11 are pressed against the end surface of the substrate W, and the substrate W is held by the plurality of chuck pins 11. Thereafter, the spin motor 14 is driven, and the rotation of the substrate W is started (step S12 in FIG. 4).

Next, a chemical liquid supply step of supplying DHF that is an example of a chemical liquid onto the upper surface of the substrate W is performed (step S13 of FIG. 4).

Specifically, the nozzle actuator 37 moves the chemical liquid nozzle 31 and the rinse liquid nozzle 32 from the standby position to the processing position. Thereafter, in a state in which the at least one guard 24 is located at the upper position, the chemical liquid valve 31v is opened, and the chemical liquid nozzle 31 starts discharging DHF. When a predetermined time elapses from when the chemical liquid valve 31v is opened, the chemical liquid valve 31v is closed and the discharge of DHF is stopped.

DHF that is discharged from the chemical liquid nozzle 31 collides with the upper surface of the substrate W that is rotating at the chemical liquid supply speed and thereafter flows outward along the upper surface of the substrate W. Therefore, DHF is supplied onto the entire upper surface of the substrate W, and a liquid film of DHF covering the entire upper surface of the substrate W is formed. When the chemical liquid nozzle 31 is discharging DHF, the nozzle actuator 37 may move the collision position so that the collision position of DHF with respect to the upper surface of the substrate W passes through the central portion and the outer peripheral portion, or may stop the collision position at the central portion. The same applies to the processing liquid supplied onto the upper surface of the substrate W after DHF as to whether or not to move the collision position.

Next, a rinse liquid supply step of supplying the carbonated water that is an example of a rinse liquid onto the upper surface of the substrate W is performed (step S14 of FIG. 4).

Specifically, in a state in which the at least one guard 24 is located at the upper position and the chemical liquid nozzle 31 and the rinse liquid nozzle 32 are located at the processing position, the carbonated water valve 32v is opened and the rinse liquid nozzle 32 starts discharging the carbonated water. Before the discharge of the carbonated water is started, a guard raising/lowering actuator 27 may vertically move at least one guard 24 in order to switch the guard 24 that receives the liquid discharged from the substrate W. Whether or not to switch the guard 24 that receives the liquid discharged from the substrate W is the same for the processing liquid supplied onto the upper surface of the substrate W after carbonated water.

The carbonated water that is discharged from the rinse liquid nozzle 32 collides with the upper surface of the substrate W that is rotating at the rinse liquid supply speed and thereafter flows outward along the upper surface of the substrate W. DHF on the substrate W is replaced with carbonated water discharged from the rinse liquid nozzle 32. Thereby, a liquid film of carbonated water covering the entire upper surface of the substrate W is formed. When a predetermined time elapses after the carbonated water valve 32v is opened, the carbonated water valve 32v is closed and the discharge of the carbonated water is stopped. Thereafter, the nozzle actuator 37 moves the chemical liquid nozzle 31 and the rinse liquid nozzle 32 to the standby position.

Next, a phosphoric acid supply step (step S15 in FIG. 4) of supplying phosphoric acid having a temperature higher than room temperature, which is an example of an etching liquid, onto the upper surface of the substrate W is performed.

Specifically, the nozzle actuator 38 moves the chemical liquid nozzle 33 from the standby position to the processing position. Thereafter, in a state in which the at least one guard 24 is located at the upper position, the chemical liquid valve 33v is opened, and the chemical liquid nozzle 33 starts discharging phosphoric acid.

Phosphoric acid that is discharged from the chemical liquid nozzle 33 collides with the upper surface of the substrate W that is rotating at the phosphoric acid supply speed and thereafter flows outward along the upper surface of the substrate W. The carbonated water on the substrate W is replaced with the phosphoric acid discharged from the chemical liquid nozzle 33. Thereby, a liquid film of phosphoric acid covering the entire upper surface of the substrate W is formed. When a predetermined time elapses from when the third chemical liquid valve 33v is opened, the chemical liquid valve 33v is closed and the discharge of phosphoric acid is stopped. Thereafter, the nozzle actuator 38 moves the chemical liquid nozzle 33 to the standby position.

The phosphoric acid supply step may or may not include a film thickness reducing step in addition to the phosphoric acid discharging step. The phosphoric acid discharging step is a step of maintaining a state in which the entire upper surface of the substrate W is covered with a liquid film of phosphoric acid while causing the chemical liquid nozzle 33 to discharge phosphoric acid toward the upper surface of the substrate W. The film thickness reducing step is a step of reducing the film thickness, that is, the thickness of the liquid film while maintaining a state in which the entire upper surface of the substrate W is covered with the liquid film of phosphoric acid when the chemical liquid nozzle 33 stops discharging phosphoric acid.

Next, a first hot water supply step (step S16 in FIG. 4) of supplying first hot water, which is an example of a rinse liquid, onto the upper surface of the substrate W is performed.

Specifically, the nozzle actuator 39 moves the chemical liquid nozzle 34 and the rinse liquid nozzle 35 from the standby position to the processing position. Thereafter, the hot water valve 35v is opened, and the rinse liquid nozzle 35 starts discharging the first hot water.

The first hot water that is discharged from the rinse liquid nozzle 35 collides with the upper surface of the substrate W that is rotating at the first hot water supply speed and thereafter flows outward along the upper surface of the substrate W. The phosphoric acid on the substrate W is replaced with the first hot water discharged from the rinse liquid nozzle 35. Thereby, a liquid film of the first hot water covering the entire upper surface of the substrate W is formed. When a predetermined time elapses after the hot water valve 35v is opened, the hot water valve 35v is closed and the discharge of the first hot water is stopped.

The first hot water supply step may or may not include a puddle step of stagnating the first hot water on the upper surface of the substrate W while maintaining a state in which the entire upper surface of the substrate W is covered with the liquid film of the first hot water. The puddle step is a step of maintaining a state in which the entire upper surface of the substrate W is covered with the liquid film of the first hot water by standing the substrate W still or rotating the substrate W at a low speed (for example, a rotational speed of more than 0 and 50 rpm or less) while discharging the first hot water toward the upper surface of the substrate W or without discharging the first hot water toward the upper surface of the substrate W.

Next, an alkaline chemical liquid supply step (step S17 in FIG. 4) of supplying SC1, which is an example of the alkaline chemical liquid, onto the upper surface of the substrate W is performed.

Specifically, in a state in which the at least one guard 24 is located at the upper position and the chemical liquid nozzle 34 and the rinse liquid nozzle 35 are located at the processing position, the chemical liquid valve 34v is opened and the chemical liquid nozzle 34 starts discharging SC1.

SC1 discharged from the chemical liquid nozzle 34 collides with the upper surface of the substrate W that is rotating at the alkaline chemical liquid supply speed, and then flows outward along the upper surface of the substrate W. The first hot water on the substrate W is replaced with SC1 discharged from the rinse liquid nozzle 35. Thereby, a liquid film of SC1 covering the entire upper surface of the substrate W is formed. When a predetermined time elapses from when the chemical liquid valve 34v is opened, the chemical liquid valve 34v is closed and the discharge of SC1 is stopped.

Next, a second hot water supply step (step S18 in FIG. 4) of supplying second hot water, which is an example of a rinse liquid, onto the upper surface of the substrate W is performed.

Specifically, in a state in which the at least one guard 24 is located at the upper position and the chemical liquid nozzle 34 and the rinse liquid nozzle 35 are located at the processing position, the hot water valve 35v is opened and the rinse liquid nozzle 35 starts discharging the second hot water.

The second hot water that is discharged from the rinse liquid nozzle 35 collides with the upper surface of the substrate W that is rotating at the second hot water supply speed and thereafter flows outward along the upper surface of the substrate W. SC1 on the substrate W is replaced with the second hot water discharged from the rinse liquid nozzle 35. Thereby, a liquid film of the second hot water covering the entire upper surface of the substrate W is formed. When a predetermined time elapses after the hot water valve 35v is opened, the hot water valve 35v is closed and the discharge of the second hot water is stopped.

The rotation speed of the substrate W may be constant from the beginning to the end of the period in which the second hot water is supplied onto the substrate W, or may change during the same period. In the latter case, the second hot water supply step may include a low-speed step and a high-speed step. The low-speed step is a step of rotating the substrate W at a low rotation speed equal to or lower than the rotation speed of the substrate W at the time of supplying SC1 while discharging the second hot water from the rinse liquid nozzle 35 toward the upper surface of the substrate W. The high-speed step is a step of rotating the substrate W at a high rotation speed exceeding the rotation speed of the substrate W at the time of supplying SC1 while discharging the second hot water from the rinse liquid nozzle 35 toward the upper surface of the substrate W.

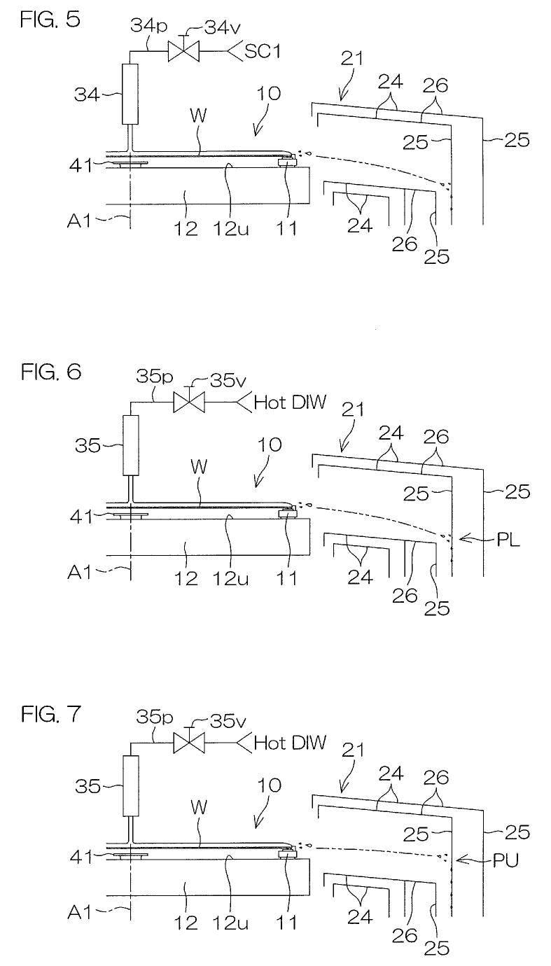

FIGS. 5, 6, and 7, are schematic views of the substrate W and the guard 24 viewed horizontally when the processing liquid is discharged toward the upper surface of the substrate W while the substrate W is rotated. FIG. 5 shows a state in which SC1 is discharged toward the upper surface of the substrate W, and FIGS. 6 and 7 show a state in which second hot water is discharged toward the upper surface of the substrate W. FIG. 6 shows a state in which the substrate W rotates at a low rotation speed, and FIG. 7 shows a state in which the substrate W rotates at a high rotation speed.

The second hot water scattered from the substrate W when the substrate W is rotating at a low rotation speed or a high rotation speed collides with the inner surface of the guard 24 directly facing the substrate W in the horizontal direction. The guard 24 that receives the second hot water scattered from the substrate W may be the same as, or different from the guard 24 that receives SC1 scattered from the substrate W. FIGS. 5 and 6 how an example of the former.

As can be seen by comparing FIGS. 6 and 7, the second hot water scattered from the substrate W when the substrate W is rotating at a high rotation speed collides with the inner surface of the guard 24 at an upper collision position PU above a lower collision position PL where the second hot water collides with the inner surface of the guard 24 when the substrate W is rotating at a low rotation speed. During the period until the rotation speed of the substrate W raises from the low rotation speed to the high rotation speed, the second hot water scattered from the substrate W collides with the intermediate range of the inner surface of the guard 24, that is, the range between the lower collision position PL and the upper collision position PU. Thereafter, the second hot water flows down from the upper collision position PU or the intermediate range along the inner surface of the guard 24.

After the second hot water is supplied onto the upper surface of the substrate W, a final rinse liquid supply step (step S19 in FIG. 4) of supplying carbonated water that is an example of the final rinse liquid to the upper surface of the substrate W is performed.

Specifically, in a state in which the at least one guard 24 is located at the upper position and the chemical liquid nozzle 34 and the rinse liquid nozzle 35 are located at the processing position, the carbonated water valve 36v is opened and the rinse liquid nozzle 35 starts discharging the carbonated water.

The carbonated water that is discharged from the rinse liquid nozzle 35 collides with the upper surface of the substrate W that is rotating at the final rinse liquid supply speed and thereafter flows outward along the upper surface of the substrate W. The second hot water on the substrate W is replaced with carbonated water discharged from the rinse liquid nozzle 35. Thereby, a liquid film of carbonated water covering the entire upper surface of the substrate W is formed. When a predetermined time elapses after the carbonated water valve 36v is opened, the carbonated water valve 36v is closed and the discharge of the carbonated water is stopped. Thereafter, the nozzle actuator 39 moves the chemical liquid nozzle 34 and the rinse liquid nozzle 35 from the processing position to the standby position.

Next, a spin drying step of drying the substrate W by rotation of the substrate W is performed (step 20 of FIG. 4).

Specifically, the spin motor 14 accelerates the substrate W in the rotation direction. Thereby, the substrate W rotates at a drying speed (for example, a rotation speed exceeding 1000 rpm) higher than the rotation speed when the processing liquid such as a chemical liquid is supplied onto the substrate W. When the substrate W rotates at a drying speed, the liquid is removed from the substrate W, and the substrate W is dried. Thereafter, the spin motor 14 stops the rotation. The rotation of the substrate W is thereby stopped (step S21 of FIG. 4).

Next, a carry-out step (step S22 of FIG. 4) of carrying out the substrate W from the chamber 4 is performed.

Specifically, the guard raising/lowering actuator 27 lowers all the guards 24 to the lower position. Thereafter, the center robot CR causes the hand Hc to enter the chamber 4. After the plurality of chuck pins 11 release the gripping of the substrate W, the center robot CR supports the substrate W on the spin chuck 10 with the hand Hc. Thereafter, the center robot CR makes the hand Hc come out of the chamber 4 while supporting the substrate W with the hand Hc. Thereby, the processed substrate W is carried out from the chamber 4.

Next, an example of processing conditions of the substrates W as shown in FIG. 4 will be described.

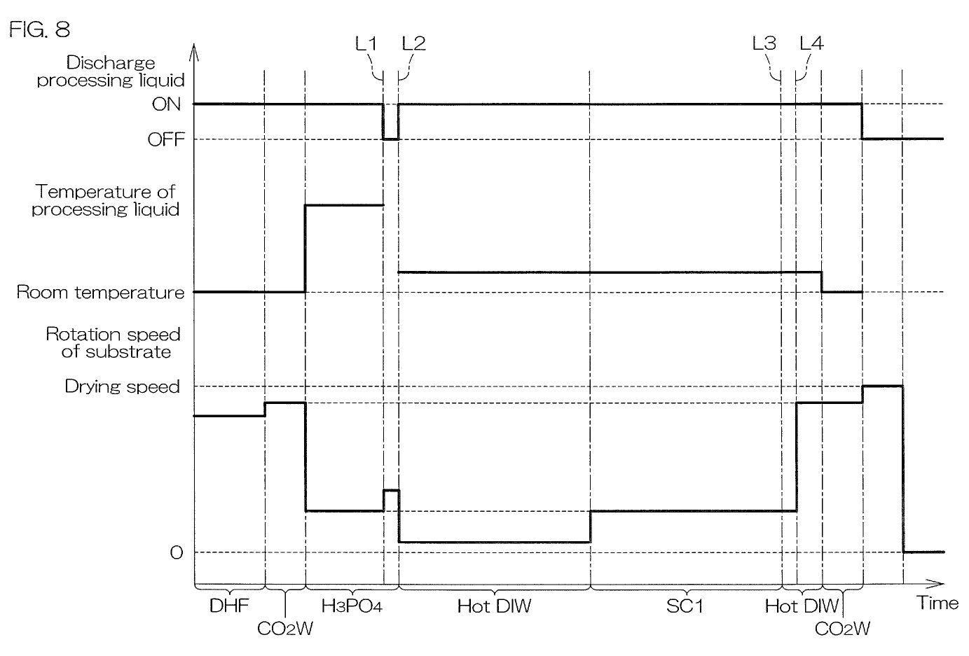

FIG. 8 is a time chart showing the discharge of the processing liquid, the temperature of the processing liquid, and the rotation speed of the substrate W when the processing shown in FIG. 4 is performed. Hereinafter, in order to distinguish between carbonated water supplied onto the upper surface of the substrate W before phosphoric acid is supplied and carbonated water supplied onto the upper surface of the substrate W after SC1 is supplied, the carbonated water supplied onto the upper surface of the substrate W after SC1 is supplied is referred to as a final rinse liquid.

First, the temperature of the processing liquid when supplied onto the upper surface of the substrate W will be described.

The temperature of DHF is higher than the coagulation point of DHF and lower than the boiling point of water (at 1 atm, the same applies hereinafter). Similarly, the temperature of the carbonated water is higher than the coagulation point of the carbonated water and lower than the boiling point of water. FIG. 8 shows an example in which the temperature of DHF and the temperature of carbonated water are at room temperature. The temperature of DHF may be equal to or higher or lower than the temperature of the carbonated water. The temperature of DHF may be equal to or higher or lower than the temperature of the first hot water (in FIG. 8, HotDIW on left). Similarly, the temperature of DHF may be equal to or higher or lower than the temperature of the second hot water (in FIG. 8, HotDIW on right). The same applies to carbonated water.

The temperature of phosphoric acid is higher than the boiling point of water and lower than or equal to the boiling point of phosphoric acid. The temperature of the phosphoric acid is higher than the temperatures of the first hot water, SC1, second hot water, and final rinse liquid. The temperature of the first hot water is higher than room temperature and lower than the boiling point of water. Similarly, the temperature of the second hot water is higher than room temperature and lower than the boiling point of water. The temperature of SC1 is higher than the coagulation point of SC1 and lower than the boiling point of water. Similarly, the temperature of the final rinse liquid is higher than the coagulation point of the final rinse liquid and lower than the boiling point of water.

FIG. 8 shows an example in which the temperature of the first hot water, the temperature of SC1, and the temperature of the second hot water are equal, and the temperature of the final rinse liquid is room temperature. The temperature of the first hot water may be equal to or higher or lower than the temperature of SC1, second hot water, or final rinse liquid. The temperature of SC1 may be equal to or higher or lower than the temperature of the second hot water or the final rinse liquid. The temperature of the second hot water may be equal to or higher or lower than the temperature of the final rinse liquid.

Next, the supply time of the processing liquid onto the upper surface of the substrate W will be described.

In FIG. 8, the length of a curly bracket (also referred to as a squiggly bracket) in the left-right direction represents the supply time of the processing liquid with respect to the upper surface of the substrate W. For example, in FIG. 8, curly brackets above DHF are shorter in the left-right direction than curly brackets above SC1. This indicates that the supply time of DHF is shorter than the supply time of SC1.

The supply time of the processing liquid is a period (for example, a period from a time point when the DHF first comes into contact with the upper surface of the substrate W to a time point when all of the DHF disappears from the upper surface of the substrate W) from a time point at which the processing liquid first comes into contact with the upper surface of the substrate W to a time point at which all of the processing liquid disappears from the upper surface of the substrate W. However, when an extremely traced amount of the processing liquid (for example, a processing liquid to an extent that cannot be visually confirmed) remains on the upper surface of the substrate W, it is considered that all of the processing liquid has disappeared from the upper surface of the substrate W. When the nozzle discharges the processing liquid toward the upper surface of the substrate W, if the processing liquid remains on the upper surface of the substrate W, the time after the nozzle stops discharging the processing liquid is also included in the supply time of the processing liquid.

Phosphoric acid is supplied onto the upper surface of the substrate W after DHF and carbonated water are supplied onto the upper surface of the substrate W. The supply time of phosphoric acid may be equal to or longer or shorter than the supply time of DHF or carbonated water. The supply time of DHF may be equal to or longer or shorter than the supply time of carbonated water. FIG. 8 shows an example in which the supply time of phosphoric acid is longer than the supply time of DHF, and the supply time of DHF is longer than the supply time of carbonated water.

After the phosphoric acid is supplied onto the upper surface of the substrate W, the first hot water is supplied onto the upper surface of the substrate W. The supply time of the first hot water may be equal to or longer or shorter than the supply time of DHF, carbonated water, or phosphoric acid. FIG. 8 shows an example in which the supply time of the first hot water is longer than the supply time of phosphoric acid. In this example, the supply time of the first hot water is longer than both the supply time of DHF and the supply time of carbonated water.

After the first hot water is supplied onto the upper surface of the substrate W, SC1 is supplied onto the upper surface of the substrate W. The supply time of SC1 may be equal to or longer or shorter than the supply time of DHF, carbonated water, phosphoric acid, or first hot water. FIG. 8 shows an example in which the supply time of SC1 is equal to the supply time of the first hot water. In this example, the supply time of SC1 is longer than any of the supply time of DHF, the supply time of carbonated water, and the supply time of phosphoric acid.

After SC1 is supplied onto the upper surface of the substrate W, the second hot water is supplied onto the upper surface of the substrate W. The supply time of the second hot water may be equal to or longer or shorter than the supply time of DHF, carbonated water, phosphoric acid, first hot water, or SC1. FIG. 8 shows an example in which the supply time of the second hot water is shorter than the supply time of DHF.

FIG. 8 shows an example in which the second hot water step includes a low-speed step and a high-speed step. A boundary line L3 and a boundary line L4 in FIG. 8 represent the start and end of the low-speed step. In the example shown in FIG. 8, the period of the low-speed step is shorter than the period of the high-speed step. In other words, the period during which the substrate W is rotating at a low rotation speed and the second hot water is in contact with the upper surface of the substrate W is shorter than the period during which the substrate W is rotating at a high rotation speed and the second hot water is in contact with the upper surface of the substrate W. The period of the low-speed step may be equal to or longer or shorter than the period of the high speed step.

Next, the rotation speed of the substrate W will be described.

In the following description, in a case where the rotation speed of the substrate W changes when the processing liquid is in contact with the substrate W, unless otherwise specified, the rotation speed of the substrate W at the time of supplying the processing liquid means the maximum value of the same rotation speed. For example, in FIG. 8, the rotation speed of the substrate W increases in a period from the boundary line L1 to the boundary line L2. In this case, the rotational speed of the substrate W at the time of supplying phosphoric acid means the rotational speed during the period from the boundary line L1 to the boundary line L2.

FIG. 8 shows an example in which the phosphoric acid supply step includes a phosphoric acid discharging step and a film thickness reducing step. The boundary line L1 and the boundary line L2 in FIG. 8 represent the start and the end of the film thickness reducing step. In the example shown in FIG. 8, the rotation speed of the substrate W in the film thickness reducing step is higher than the rotation speed of the substrate W in the phosphoric acid discharging step, and is lower than both the rotation speed of the substrate W at the time of supplying DHF and the rotation speed of the substrate W at the time of supplying carbonated water. The rotation speed of the substrate W at the time of supplying phosphoric acid may be equal to the rotation speed of the substrate W at the time of supplying DHF or carbonated water, or may be higher or lower than such a rotation speed.

FIG. 8 shows an example in which the rotation speed of the substrate W at the time of supplying the first hot water is lower than the rotation speed of the substrate W at the time of supplying phosphoric acid. In this example, the rotation speed of the substrate W at the time of supplying the first hot water is lower than the rotation speed of the substrate W in the phosphoric acid discharging step. The rotation speed of the substrate W at the time of supplying the first hot water may be equal to the rotation speed of the substrate W at the time of supplying phosphoric acid, or may be higher or lower than such a rotation speed. More specifically, the rotation speed of the substrate W at the time of supplying the first hot water may be equal to the rotation speed of the substrate W in the phosphoric acid discharging step or the film thickness reducing step, or may be higher or lower than such a rotation speed.

FIG. 8 shows an example in which the rotation speed of the substrate W at the time of supplying SC1 is higher than the rotation speed of the substrate W at the time of supplying the first hot water and is equal to the rotation speed of the substrate W in the phosphoric acid discharging step. The rotation speed of the substrate W at the time of supplying SC1 may be equal to the rotation speed of the substrate W at the time of supplying phosphoric acid or the first hot water, or may be higher or lower than such a rotation speed. The rotation speed of the substrate W at the time of supplying SC1 may be a value between the rotation speed of the substrate W at the time of supplying phosphoric acid and the rotation speed of the substrate W at the time of supplying the first hot water. FIG. 8 shows this example.

The rotation speed of the substrate W at the time of supplying the second hot water may be equal to the rotation speed of the substrate W at the time of supplying SC1, or may be higher or lower than such a rotation speed. FIG. 8 shows an example in which the second hot water supply step includes a low-speed step and a high-speed step. That is, FIG. 8 shows an example in which there are a period in which the rotation speed of the substrate W at the time of supplying the second hot water is equal to or lower than the rotation speed of the substrate W at the time of supplying SC1 (a period in which the rotation speed of the substrate W is low) and a period in which the rotation speed of the substrate W at the time of supplying the second hot water exceeds the rotation speed of the substrate W at the time of supplying SC1 (a period in which the rotation speed of the substrate W is high).

In the example shown in FIG. 8, the low rotation speed (rotation speed of the substrate W in the low-speed step) is equal to the rotation speed of the substrate W at the time of supplying SC1, and the high rotation speed (rotation speed of the substrate W in the high-speed step) is higher than the rotation speed of the substrate W at the time of supplying SC1. The high rotation speed is lower than the drying speed (rotation speed of the substrate W in the spin drying step). The high rotation speed may be equal to the rotation speed of the substrate W at the time of supplying phosphoric acid, or may be lower than such a rotation speed. FIG. 8 shows an example of the former.

The rotation speed of the substrate W at the time of supplying the final rinse liquid is lower than the drying speed. The rotation speed of the substrate W at the time of supplying the final rinse liquid may be equal to the rotation speed of the substrate W at the time of supplying the second hot water, or may be higher or lower than such a rotation speed. FIG. 8 shows an example in which the rotation speed of the substrate W at the time of supplying the final rinse liquid is equal to the rotation speed of the substrate W in the high-speed step.

Next, the advantages according to the preferred embodiment will be described.

In the present preferred embodiment, phosphoric acid, the first hot water, SC1, and the second hot water are sequentially supplied onto the upper surface of the substrate W in this order. Specifically, phosphoric acid is supplied onto the upper surface of the substrate W while the substrate W is rotated in a horizontal posture. Similarly, while rotating the substrate W in a horizontal posture, the first hot water, SC1, and second hot water are individually supplied onto the upper surface of the substrate W. Phosphoric acid on the substrate W is replaced with the first hot water. The first hot water on the substrate W is replaced by SC1. SC1 on the substrate W is replaced with the second hot water.

Both the first hot water and the second hot water are pure water having a temperature higher than room temperature. When phosphoric acid, the first hot water, SC1, and the second hot water are sequentially supplied onto the upper surface of the substrate W in this order, foreign matters such as a compound containing phosphorus (P) are reduced as compared with a case where pure water at room temperature is used instead of the second hot water under the same conditions. This is because when the temperature of the pure water increases, the foreign matters are easily dissolved in the pure water. Therefore, by sequentially supplying phosphoric acid, the first hot water, SC1, and the second hot water onto the upper surface of the substrate W in this order, the cleanliness level of the substrate W can be enhanced.

In the present preferred embodiment, the time during which the first hot water is in contact with the upper surface of the substrate W is longer than the time during which the phosphoric acid is in contact with the upper surface of the substrate W. This increases the time during which the phosphoric acid or foreign matters on the substrate W dissolves in the first hot water. As a result, as compared with a case where the supply time of the first hot water with respect to the upper surface of the substrate W is equal to or less than the supply time of the phosphoric acid with respect to the upper surface of the substrate W, it is possible to reduce the phosphoric acid and foreign matters remaining on the upper surface of the substrate W, and it is possible to increase the cleanliness level of the substrate W.

In the present preferred embodiment, phosphoric acid is supplied onto the upper surface of the substrate W while the substrate W is rotated in a horizontal posture at the phosphoric acid supply speed. Thereafter, while the substrate W is rotated in a horizontal posture at the first hot water supply speed lower than the phosphoric acid supply speed, a state in which the entire upper surface of the substrate W is covered with the liquid film of the first hot water is maintained. Alternatively, the same state is maintained while the substrate W is stopped in a horizontal posture. In the same state, since the substrate W rotates at a relatively low speed or stands still, the time from when the first hot water is supplied onto the substrate W to when the first hot water is discharged from the substrate W increases. Thereby, it is possible to increase the time during which the phosphoric acid and the foreign matters are dissolved in the first hot water, and it is possible to reduce the phosphoric acid and the foreign matters remaining on the upper surface of the substrate W.

In the present preferred embodiment, before the phosphoric acid is supplied, the pre-wet liquid is supplied onto the upper surface of the substrate W while the substrate W is rotated in a horizontal posture. Thereafter, phosphoric acid is supplied onto the upper surface of the substrate W while the substrate W is rotated in a horizontal posture. The chemical liquid such as DHF is an example of the pre-wet liquid. The rinse liquid such as carbonated water is another example of the pre-wet liquid. The rotation speed of the substrate W at the time of supplying phosphoric acid is lower than the rotation speed of the substrate W at the time of supplying the pre-wet liquid. The rotation speed of the substrate W at the time of supplying the first hot water is lower than the rotation speed of the substrate W at the time of supplying phosphoric acid.

Since the rotation speed of the substrate W at the time of supplying phosphoric acid is relatively low, a decrease in the temperature of phosphoric acid on the substrate W can be alleviated. Thereby, a state in which the temperature of the phosphoric acid is high can be maintained, and the etching rate of the substrate W by the phosphoric acid can be maintained at a high value. In addition, since the rotation speed of the substrate W at the time of supplying phosphoric acid is low and the rotation speed of the substrate W at the time of supplying the first hot water is further low, when the first hot water is in contact with the upper surface of the substrate W, the rotation of the substrate W is relatively slow. Thereby, the time from when the first hot water is supplied onto the substrate W to when the first hot water is discharged from the substrate W can be further increased, and phosphoric acid and foreign matters remaining on the upper surface of the substrate W can be reduced.

In the present preferred embodiment, the time during which SC1 is in contact with the upper surface of the substrate W is longer than the time during which the phosphoric acid is in contact with the upper surface of the substrate W. When phosphoric acid remains on the upper surface of the substrate W, SC1 reacts with phosphoric acid and a salt such as ammonia phosphate is produced. This salt is discharged from the substrate W together with at least one of SC1 and the second hot water. Since the supply time of the alkaline chemical liquid is relatively long, the time for SC1 to react with phosphoric acid can be increased. This makes it possible to reduce phosphoric acid remaining on the upper surface of the substrate W.

In the present preferred embodiment, SC1 is supplied onto the upper surface of the substrate W while rotating the substrate W at a rotation speed (alkaline chemical liquid supply speed) equal to or lower than the rotation speed (phosphoric acid supply speed) of the substrate W when phosphoric acid is supplied onto the substrate W. Therefore, as compared with the case where the alkaline chemical liquid supply speed is higher than the phosphoric acid supply speed, the time from when SC1 is supplied onto the substrate W to when SC1 is discharged from the substrate W can be increased, and the time for SC1 to react with phosphoric acid remaining on the upper surface of the substrate W can be increased.

In the present preferred embodiment, the second hot water is supplied onto the upper surface of the substrate W while rotating the substrate W at a low rotation speed equal to or lower than the rotation speed (alkaline chemical liquid supply speed) of the substrate W when SC1 is supplied onto the substrate W. Further, while the second hot water is supplied onto the upper surface of the substrate W, the rotational speed of the substrate W is increased from a low rotation speed to a high rotation speed exceeding the alkaline chemical liquid supply speed. Moreover, the second hot water is supplied onto the upper surface of the substrate W while the substrate W is rotated at a high rotation speed.

The second hot water scattered from the substrate W collides with the same guard 24, that is, the inner surface of the guard 24 that has received SC1. When the rotation speed of the substrate W is the same as or substantially the same as the alkaline chemical liquid supply speed, most of the second hot water collides with the inner surface of the guard 24 at or near the position where SC1 collides with the inner surface of the guard 24 (SC1 collision position). When the rotation speed of the substrate W is lower than the alkaline chemical liquid supply speed, most of the second hot water collides with the inner surface of the guard 24 at a position lower than the SC1 collision position. When the rotation speed of the substrate W is higher than the alkaline chemical liquid supply speed, most of the second hot water collides with the inner surface of the guard 24 at a position higher than the SC1 collision position. Thereafter, the second hot water flows down along the inner surface of the guard 24. Therefore, the second hot water is supplied onto all or almost all the range where SC1 is in contact with the inner surface of the guard 24.

When the substrate W is rotating at a high rotation speed, the amount of foreign matters (phosphorus-containing compound, SC1, or the like) contained in the second hot water scattered from the substrate W is smaller than that when the substrate W is rotating at a low rotation speed. Thereby, the range where the foreign matters such as SC1 adhere can be cleaned with the second hot water having high cleanliness level, and the foreign matters remaining on the inner surface of the guard 24 can be reduced. Furthermore, since the rotation speed of the substrate W is increased from the low rotation speed to the high rotation speed while the second hot water is supplied onto the upper surface of the substrate W, the second hot water scattered from the substrate W can directly collide with the intermediate range of the inner surface of the guard 24, that is, the range between a lower collision position PL (see FIG. 6) where the second hot water collides with the inner surface of the guard 24 when the substrate W is rotating at the low rotation speed and an upper collision position PU (see FIG. 7) where the second hot water collides with the inner surface of the guard 24 when the substrate W is rotating at the high rotation speed. Thereby, foreign matters remaining on the inner surface of the guard 24 can be further reduced.

In the present preferred embodiment, after the second hot water is supplied onto the upper surface of the substrate W, the substrate W is rotated at a drying speed higher than the rotation speed of the substrate W when the second hot water is supplied onto the substrate W (the above-described high rotation speed) to dry the substrate W. When the substrate W is being dried, the substrate W is located inside the guard 24 when the substrate W is viewed vertically. At this time, the substrate W may or may not directly face the inner surface of the guard 24 in the horizontal direction.

When the substrate W is rotated at a high speed, a strong airflow is generated around the substrate W. When foreign matters such as a phosphorus-containing compound adhere to the inner surface of the guard 24, the foreign matters may be carried from the guard 24 to the upper surface of the substrate W by the airflow. As described above, since all or almost all of the area where SC1 has come into contact with the inner surface of the guard 24 is cleaned with the second hot water, the amount of foreign matters adhering to the inner surface of the guard 24 is small. Therefore, even if the substrate W is dried by spin drying, foreign matter moving from the guard 24 to the upper surface of the substrate W can be eliminated or reduced.

In the present preferred embodiment, the substrate W is held horizontally by pressing the plurality of chuck pins 11 against the end surface of the substrate W. In this state, the substrate W is rotated by rotating the plurality of chuck pins 11. Phosphoric acid, the first hot water, SC1, and the second hot water are supplied onto the upper surface of the substrate W horizontally held by the plurality of chuck pins 11. The surface of the chuck pin 11 includes a side surface in contact with the end surface of the substrate W, and a top surface disposed above the side surface and the upper surface of the substrate W. Phosphoric acid on the substrate W or phosphoric acid discharged from the substrate W comes into contact with the surface of the chuck pin 11. Similarly, the first hot water, SC1, and the second hot water also come into contact with the surface of the chuck pin 11. Phosphoric acid adhering to the surface of the chuck pin 11 is washed away by the first hot water, SC1, and the second hot water.

If the rotation speed of the substrate W when at least one of the first hot water, SC1, and the second hot water is supplied onto the upper surface of the substrate W is relatively low, the time during which at least one of the first hot water, SC1, and the second hot water comes into contact with the surface of the chuck pin 11 increases. Thereby, it is possible to reduce foreign matters (such as a compound containing phosphoric acid or phosphorus) remaining on the surface of the chuck pin 11. Even when the time to supply at least one of the first hot water, SC1, and the second hot water onto the upper surface of the substrate W is relatively long, foreign matters remaining on the surface of the chuck pin 11 can be reduced. Thereby, foreign matters moving from the surface of the chuck pin 11 to the upper surface of the substrate W can be reduced, and the cleanliness level of the substrate W can be increased.

It has been confirmed that the number of particles on the upper surface of the substrate W increases as the elapsed time from the end of the processing of the substrate W increases. A queue time is defined as the time from the time point when the processing of the substrate W is completed to the time point when the number of particles on the upper surface of the substrate W reaches the maximum number that can be measured by the particle counter. It was confirmed that increasing the supply time of SC1 at a temperature higher than room temperature increases the queue time. It was confirmed that when the supply time of the first hot water is increased, the queue time is increased. When phosphoric acid, the first hot water, SC1, and the second hot water are sequentially supplied onto the upper surface of the substrate W in this order, it was confirmed that the queue time is increased as compared with the case where pure water at room temperature is used instead of the second hot water under the same conditions.

Next, other preferred embodiments will be described.

In the example of the processing of the substrate W described above, instead of SC1 at a temperature higher than room temperature, SC1 at room temperature may be supplied onto the upper surface of the substrate W.

In the above-described example of the processing of the substrate W, an alkaline chemical liquid other than SC1 may be supplied onto the upper surface of the substrate W. For example, a mixed liquid of TMY (trimethyl -2 hydroxyethyl ammonium hydroxide) and hydrogen peroxide solution may be supplied onto the upper surface of the substrate W instead of SC1. The mixed liquid of TMY and hydrogen peroxide solution is also referred to as NC2. TMY is also referred to as choline.

The final rinse liquid may be a liquid other than carbonated water. For example, the substrate W may be dried after carbonated water on the substrate W is replaced with IPA. In this case, carbonated water corresponds to the intermediate rinse liquid, and IPA corresponds to the final rinse liquid. The substrate W may be dried after the second hot water on the substrate W is replaced with IPA. The substrate W wetted with the second hot water may be dried. That is, the second hot water may be the final rinse liquid.

The substrate W may be dried by a method other than spin drying. For example, after the second hot water is supplied onto the upper surface of the substrate W, IPA may be supplied onto the upper surface of the substrate W and replaced with a sublimation substance-containing liquid. In this case, the sublimation substance-containing liquid on the substrate W may be removed from the upper surface of the substrate W by changing the sublimation substance-containing liquid into a solid or semi-solid solidified film and then sublimating the solidified film on the substrate W.

At least one of the chemical liquid nozzle 31, the chemical liquid nozzle 33, the chemical liquid nozzle 34, the rinse liquid nozzle 32, and the rinse liquid nozzle 35 may discharge the processing liquid toward the upper surface of the substrate W from a plurality of discharge ports arranged at a plurality of positions having different distances in the horizontal direction from the center of the upper surface of the substrate W. In this case, the single nozzle having only one discharge port and the multi-nozzle provided with the plurality of discharge ports as described above may simultaneously discharge the processing liquid having the same substances and temperature toward the upper surface of the substrate W. When the single nozzle discharges the processing liquid toward the central portion of the upper surface of the substrate W, the multi-nozzle may discharge the processing liquid toward a plurality of positions in the upper surface of the substrate W other than the central portion.

The substrate processing apparatus 1 may be an apparatus to process a polygonal substrate W.

Two or more arrangements among all the arrangements described above may be combined. Two or more steps among all the steps described above may be combined.

The preferred embodiments of the present invention are described in detail above, however, these are just detailed examples used for clarifying the technical contents of the present invention, and the present invention should not be limitedly interpreted to these detailed examples, and the spirit and scope of the present invention should be limited only by the claims appended hereto.

What is claimed is:

1. A substrate processing method comprising:
supplying phosphoric acid having a temperature higher than room temperature onto an upper surface of a substrate while rotating the substrate in a horizontal posture;
supplying first hot water, which is pure water having a temperature higher than room temperature, onto the upper surface of the substrate while rotating the substrate in a horizontal posture with the phosphoric acid on the upper surface of the substrate;
supplying an alkaline chemical liquid onto the upper surface of the substrate while rotating the substrate in a horizontal posture with the first hot water on the upper surface of the substrate; and
supplying second hot water, which is pure water having a temperature higher than room temperature, onto the upper surface of the substrate while rotating the substrate in a horizontal posture with the alkaline chemical liquid on the upper surface of the substrate.

2. The substrate processing method according to claim 1, wherein a supply time of the first hot water with respect to the upper surface of the substrate is longer than a supply time of the phosphoric acid with respect to the upper surface of the substrate.

3. The substrate processing method according to claim 1, wherein
supplying the phosphoric acid includes supplying the phosphoric acid onto the upper surface of the substrate while rotating the substrate in a horizontal posture at a phosphoric acid supply speed, and
supplying the first hot water includes maintaining a state in which an entire area of the upper surface of the substrate is covered with a liquid film of the first hot water while rotating the substrate in a horizontal posture at a first hot water supply speed lower than the phosphoric acid supply speed or stopping the substrate in a horizontal posture.

4. The substrate processing method according to claim 3, further comprising supplying a pre-wet liquid onto the upper surface of the substrate while rotating the substrate in a horizontal posture at a pre-wet liquid supply speed before supplying the phosphoric acid onto the upper surface of the substrate,
wherein supplying the phosphoric acid includes supplying the phosphoric acid onto the upper surface of the substrate while rotating the substrate in a horizontal posture at the phosphoric acid supply speed lower than the pre-wet liquid supply speed.

5. The substrate processing method according to claim 1, wherein a supply time of the alkaline chemical liquid with respect to the upper surface of the substrate is longer than a supply time of the phosphoric acid with respect to the upper surface of the substrate.

6. The substrate processing method according to claim 1, wherein
supplying the phosphoric acid includes supplying the phosphoric acid onto the upper surface of the substrate while rotating the substrate in a horizontal posture at a phosphoric acid supply speed, and
supplying the alkaline chemical liquid includes supplying the alkaline chemical liquid onto the upper surface of the substrate while rotating the substrate in a horizontal posture at an alkaline chemical liquid supply speed that is equal to or lower than the phosphoric acid supply speed.

7. The substrate processing method according to claim 1, wherein
supplying the alkaline chemical liquid includes supplying the alkaline chemical liquid onto the upper surface of the substrate while rotating the substrate in a horizontal posture at an alkaline chemical liquid supply speed to cause the alkaline chemical liquid scattered from the substrate to collide with an inner surface of a cylindrical guard surrounding the substrate around a vertical straight line, and
supplying the second hot water includes
supplying the second hot water onto the upper surface of the substrate while rotating the substrate in a horizontal posture at a low rotation speed equal to or lower than the alkaline chemical liquid supply speed to cause the second hot water scattered from the substrate to collide with the inner surface of the guard,
increasing a rotation speed of the substrate from the low rotation speed to a high rotation speed exceeding the alkaline chemical liquid supply speed while supplying the second hot water onto the upper surface of the substrate; and
supplying the second hot water onto the upper surface of the substrate while rotating the substrate in a horizontal posture at the high rotation speed to cause the second hot water scattered from the substrate to collide with the inner surface of the guard.

8. The substrate processing method according to claim 7, further comprising drying the substrate by rotating the substrate at a drying speed higher than the high rotation speed in a state in which the substrate is positioned inside the guard when viewed vertically after supplying the second hot water onto the upper surface of the substrate.

9. The substrate processing method according to claim 2, wherein supplying the phosphoric acid, supplying the first hot water, supplying the alkaline chemical liquid, and supplying the second hot water include supplying the phosphoric acid, the first hot water, the alkaline chemical liquid, and the second hot water onto the upper surface of the substrate while rotating the substrate in a horizontal posture together with a plurality of chuck pins pressed against an end surface of the substrate.
